(19) United States
(12) Patent Application Publication
(10) Pub. No.: US 2014/0269086 A1
(43) Pub. Date: Sep. 18, 2014

(54) SYSTEM AND METHOD OF ACCESSING MEMORY OF A DATA STORAGE DEVICE

(71) Applicant: SANDISK TECHNOLOGIES INC., PLANO, TX (US)

(72) Inventor: Menahem Lasser, Kohav-Yair (IL)

(73) Assignee: SANDISK TECHNOLOGIES INC., PLANO, TX (US)

(21) Appl. No.: 13/828,423

(22) Filed: Mar. 14, 2013

(51) Int. Cl. G11C 16/26

(52) U.S. Cl. CPC G11C 16/26
USPC 365/185.18

(57) ABSTRACT

Flash memory devices and methods of reading data from flash memory devices reduce an overall number of sensing operations when data is to be read from one word line in accordance with one or more flags set according to data read from another word line.

### FIELD OF THE DISCLOSURE

The present disclosure is generally related to accessing memory of a data storage device.

### BACKGROUND

Non-volatile data storage devices, such as universal serial bus (USB) flash memory devices or removable storage cards, have allowed for increased portability of data and software applications. Flash memory devices can enhance data storage density by storing multiple bits in each flash memory cell. For example, Multi-Level Cell (MLC) flash memory devices provide increased storage density by storing 3 bits per cell, 4 bits per cell, or more. Although increasing the number of bits per cell and reducing device feature dimensions may increase a storage density of a memory device, a bit error rate of data stored at the memory device may also increase.

A cross-coupling effect from an upper neighbor cell to a particular cell of a non-volatile memory that is being read causes a shifting of the particular cell's threshold voltage. The amount of the shifting depends on the state programmed into the upper neighbor cell. For example, if a higher voltage value is programmed into the upper neighbor cell, the amount of shifting is also higher. Differential Look Ahead (DLA) is a reading mode that provides a countermeasure against the shifting. In the DLA reading mode, a next word line is read and the data of the next word line is used to offset the cross-coupling effect. Reading using the DLA mode is useful for applications that require high reliability and for high density memory devices. Look Ahead (LA) is another reading mode where a cell with an upper neighbor in a high state has its reference reading voltages shifted to larger voltages, while a cell with an upper neighbor in a low state has its reference reading voltages shifted only slightly or not shifted. While reading in the LA or DLA mode may provide a countermeasure to the cross-coupling effect and shifting, reading with the LA or DLA mode may have increased latency due to extra operations performed (e.g. extra reading operations and computations).

### SUMMARY

In certain memory devices (e.g., two bits-per-cell flash memory devices), each word line has two pages (e.g., a lower page and an upper page). When reading any one of the pages of a particular word line (e.g., when using the LA mode or the DLA mode), a sequentially higher word line (e.g., WLn+1) is also read in a look-ahead read operation that may include three sense operations to read the sequentially higher word line. When reading both the lower page and the upper page of a word line (e.g., WLn) sequentially, a method and apparatus are disclosed that read the next sequential word line (WLn+1) once (instead of twice).

Additionally, when a target word line is being read following the reading of its sequentially higher neighbor word line, data generated as a result of reading the sequentially higher word line may be used for supporting reading the target word line using LA or DLA mode, thus avoiding the need for another reading of the higher word line.

### BRIEF DESCRIPTION OF THE DRAWINGS

FIG. 1 is a block diagram of a particular illustrative embodiment of a system including a data storage device configured to perform read operations that include selecting data for each bit from multiple results according to a flag corresponding to the bit;

FIG. 2 is a timing diagram illustrating a particular embodiment of a read operation that may be performed by the data storage device of FIG. 1;

FIG. 3 is a flowchart of a particular embodiment of a method of reading data;

FIG. 4 is a flowchart of another particular embodiment of a method of reading data;

FIG. 5 is a flowchart of another particular embodiment of a method of reading data;

FIG. 6 is a flowchart of another particular embodiment of a method of reading data;

FIG. 7 is a flowchart of another particular embodiment of a method of reading data; and

FIG. 8 is a flowchart of another particular embodiment of a method of reading data.

### DETAILED DESCRIPTION

Referring to FIG. 1, a particular embodiment of a system 100 includes a data storage device 102 coupled to a host device 130. The data storage device 102 is configured to perform look ahead (LA) and/or differential look ahead (DLA) mode read operations.

The host device 130 may be configured to provide data, such as user data 132, to be stored at the memory 104 or to request data to be read from the memory 104. For example, the host device 130 may include a mobile telephone, a music player, a video player, a gaming console, an electronic book reader, a personal digital assistant (PDA), a computer, such as a laptop computer or notebook computer, any other electronic device, or any combination thereof. The host device 130 communicates via a memory interface that enables reading from the memory 104 and writing to the memory 104. For example, the host device 130 may operate in compliance with a Joint Electron Devices Engineering Council (JEDEC) industry specification, such as a Universal Flash Storage (UFS) Host Controller Interface specification. As other examples, the host device 130 may operate in compliance with one or more other specifications, such as a Secure Digital (SD) Host Controller specification as an illustrative example. The host device 130 may communicate with the memory 104 in accordance with any other suitable communication protocol.

The memory 104 may be a non-volatile memory, such as a NAND flash memory. The memory 104 includes groups of storage elements, such as a first word line (WL0) 150, a second word line (WL1) 152, and a third word line (WL2) 154, of a multi-level cell (MLC) flash memory. Although three word lines (WL0-2) are shown, it should be understood that the memory 104 includes a plurality of word lines and typically includes more than the three illustrated word lines shown. Each of the word lines includes a lower page and an upper page. For example, the first word line 150 (WL0) includes a lower page 156 and an upper page 158.

The data storage device 102 may be a memory card, such as a Secure Digital SD® card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). As another example, the data storage device 102 may be configured to be coupled to the host device 130 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The controller 120 is configured to receive data and instructions from and to send data to the host device 130 while the data storage device 102 is operatively coupled to the host device 130. The controller 120 is further configured to send data and commands to the memory 104 and to receive data from the memory 104. For example, the controller 120 is configured to send data and a write command to instruct the memory 104 to store the data to a specified address. As another example, the controller 120 is configured to send a read command to read data from a specified address of the memory 104.

The data storage device 102 includes a memory die 103 that includes the memory 104. The memory die 103 also includes a flag latch 160, data latches 162, control circuitry 164, such as a state machine, and read circuitry 110. The read circuitry 110 may apply multiple voltages, such as a representative first voltage (V1) 112 and a representative second voltage (V2) 114 to a selected word line.

The controller 120 includes a read processing engine 122. The read processing engine 122 is configured to perform one or more commands. For example, representative commands include a first command 140, a second command 142, a third command 144, and a fourth command 146.

The first command 140 may be issued by the controller 120 and sent to the memory die 103 to cause LA or DLA reading to be performed to read data from a target word line according to flag data corresponding to states of one or more other storage elements (e.g., flag data indicating, for each storage element, a state of the upper neighbor of that storage element). For example, the controller 120 may send the first command 140 indicating the lower page 156, the upper page 158, or both, to the memory die 103. To illustrate, the controller 120 may send the first command 140 indicating that the lower page 156 is to be read. The control circuitry 164 (e.g., a state machine) at the memory die 103 may be responsive to the first command 140 to initiate a read operation by causing the read circuitry 110 to read the second word line 152 and to load sense data from the second word line 152 to the data latches 162. The control circuitry 164 may further cause one or more logical operations to be performed to the data in the data latches 162 to generate flag data that is copied into the flag latch 160. In a DLA implementation, the control circuitry 164 may cause the read circuitry 110 to read the target word line (e.g., the lower page 156) according to a DLA mode by selecting, for each storage element of the first word line 150, results from reading the first word line 150 while applying the first voltage 112 to the second word line 152 or results from reading the first word line 150 while applying the second voltage 114 to the second word line 152. In an LA implementation, the control circuitry 164 may cause the read circuitry 110 to read the target word line (e.g., the lower page 156) according to a LA mode by selecting, for each storage element of the target word line 150, results from reading the first word line 150 while applying the first voltage 112 to the first word line 150 or results from reading the first word line 150 while applying the second voltage 114 to the first word line 150. The selection may be based on a corresponding bit in the data in the flag latch 160. The control circuitry 164 may be configured to cause results from reading the first word line 150 to be sent to the controller 120.

The second command 142 may be issued by the controller 120 and sent to the memory die 103 to cause LA or DLA reading to be performed to read data from a target word line using existing flag data that is in the flag latch 160 when the target word line is read. In contrast to the first command 140 the next word line (e.g., the second word line 152) is not read in response to the second command 142. For example, the controller 120 may send the second command 142 indicating the lower page 156, the upper page 158, or both, to the memory die 103. To illustrate, the controller 120 may send the second command 142 indicating that the upper page 158 is to be read using the current flag data. The control circuitry 164 at the memory die 103 may be responsive to the second command 142 to cause the read circuitry 110 to read the target word line (e.g., the upper page 158) according to an LA or DLA mode. The control circuitry 164 may cause the read circuitry 110 to select, for each storage element of the first word line 150, read results corresponding to applying one of the first voltage 112 or the second voltage 114 to one of the first word line 150 or the second word line 152 based on a corresponding bit in the data in the flag latch 160 while reading data from the first word line 150. The control circuitry 164 may be configured to cause results from reading the first word line 150 to be sent to the controller 120.

The third command 144 may be issued by the controller 120 and sent to the memory die 103 to populate the flag latch 160 based on data in the data latches 162. In contrast to the first command 140 and the second command 142, the third command 144 does not cause any word line to be read. Instead, the control circuitry 164 at the memory die 103 may be responsive to the third command 144 to process data in the data latches 162 to generate flag data and to store the flag data into the flag latch 160. For example, prior to the controller 120 issuing the third command 144, the controller 120 may issue the first command 140 to read the second word line 152. As a result of processing the first command 140, the flag latch 160 may contain flag data based on the third word line 154 and the data latches 162 may contain data read from the second word line 152. To prepare for LA or DLA reading of the first word line 150, the controller 120 may issue the third command 144 to generate flag data based on the data read from the second word line 152 that is already in the data latches 162. For example, in a 2 bit-per-cell (BPC) implementation where storage element states correspond to “11” (erase state), “10” (state A), “00” (state B), or “01” (state C), where “xy” indicates an upper page bit “y” and a lower page bit “x”, a flag for each storage element may be generated as flag=(upper page bit) XOR (lower page bit). Other examples include flag=(lower page bit), flag=(NOT (upper page bit)) AND (lower page bit), or flag=(upper page bit) OR (lower page bit).

The fourth command 146 may be issued by the controller 120 and sent to the memory die 103 to populate the flag latch 160 based on data that is in the data latches 162 and to read a target page using flag data resulting from populating the flag latch 160. In contrast to the third command 144, the fourth command 146 may indicate a target page to be read after the flag latch 160 is populated. The control circuitry 164 at the memory die 103 may be responsive to the fourth command 146 to process data in the data latches 162 to generate flag data and to store the flag data into the flag latch 160 as described with respect to the third command 144. After populating the flag latch 160, the control circuitry 164 may cause the target page to be read using the flag data as described with respect to the first command 140.

The read processing engine 122 of controller 120 may reorder memory page requests received from the host device 130. For example, the host device 130 may issue a command requesting to read multiple pages in a first order, and the controller 120 may issue commands to read the multiple pages from the non-volatile memory 104 in a second order that differs from the first order. For example, the controller 120 may be configured to reorder the page reading commands to reduce a number of sensing operations that may be performed when reading data according to the LA or DLA mode.

During operation, the data storage device 102 may receive a read request 134 from the host 130. In response to the read request 134, the data storage device 102 may retrieve data from the non-volatile memory 104 and may provide resulting data 132 to the host 130. The data storage device 102 may perform an LA or DLA operation. For example, the read processing engine 122 may perform the first command 140. The first command 140 may be issued in response to the data storage device 102 receiving the read request 134 from the host device 130. The first command 140 may be executed during a sequential read operation, such as multiple read requests 134 to read data from sequential pages within the memory 104 (however, the first read command 140 may alternatively be executed during non-sequential read operations).

For example, the data storage device 102 may perform a method that includes receiving, at the flash memory 104, a command to read a first page in a first word line. For example, the memory 104 may receive the first command 140 to read a first page (e.g. the lower page 156) of the first word line 150 (WL0). The method may further include reading data stored in a second word line. For example, data within the second word line 152 (WL1) may be read. The second word line 152 is a neighbor of the first word line 150.

The data read from the second word line 152 is processed to generate flag data. For example, the data read from the second word line 152 may be stored within the data latches 162. After storing the data from the second word line 152 in the data latches 162, the data may be processed to generate the flags. For example, a logical operation may be applied to each value (e.g., a pair of bits corresponding to each MLC cell value) stored within the data latches 162, to determine whether the corresponding storage element has a threshold voltage that is defined as a “high” voltage value or as a “low” voltage value. Values that are indicated as corresponding to a high voltage may be designated with a logic “1” value (e.g., a flag set to “1”), and values that correspond to a low voltage may be designated with a logic “0” value (e.g., a flag set to “0”). Thus, the data read from the second word line 152 and stored within the data latches 162 may be processed in order to generate flag data. Each flag corresponds to a particular cell within the memory 104 and indicates whether that particular cell stores a high voltage value (e.g., flag value of “1”) or a low voltage value (e.g., flag value of “0”). The generated flag data (e.g., binary data) may be written to the flag latch 160. Thus, the flag latch 160 includes a plurality of flags (e.g., a plurality of bits), where each bit indicates a high voltage value or a low voltage value corresponding to a respective cell within a word line (e.g. the second word line 152 (WL1)).

After the flags have been stored in the flag latch 160, the method further includes reading the first page (e.g., the lower page 156), at a first time, while applying a first voltage to one of the first word line 150 (in LA mode) or the second word line 152 (in DLA mode) to generate first sense data. Thereafter, the first page 156 is read, at a second time, while applying a second voltage to the one of the first word line 150 or the second word line 152 to generate second sense data. For example, the first page 156 may be read (at a first time) while applying the first voltage 112 to the second word line 152 to generate first sense data, and subsequently, the first page 156 may be read (at a second time) while applying the second voltage 114 to the second word line 152 to generate second sense data. Depending on the value of the flags stored within the flag latch 160, either the first sense data or the second sense data, for each cell of the first word line 150, is selected to determine first page data. For example, in a DLA implementation, if a flag corresponding to a particular cell within a word line indicates a high voltage value then the first sensed data corresponding to reading the lower page 156 while applying the high voltage value (e.g., V1 (112)) to the second word line 152 is used. Alternatively, if the flag within the flag latch 160 corresponds to a low voltage value, then the second sensed data resulting from reading the lower page 156 while applying the lower voltage (e.g. the voltage V2 (114)) to the second word line 152 is used. Once the first page data has been determined, the first page data 132 is provided to the host 130 in response to the read request 134.

After the first read operation is completed, a second command (e.g., a second read request command 134) may be sent by the host device 130 to the data storage device 102. In response to receiving the second command to read a second page (e.g., the upper page 158) within the first word line 150, the controller 120 may issue the second command 142 to read the second page 158 (at a third time) while applying the first voltage (e.g. V1 (112)) to the second word line 152 to generate third sense data and the second page 158 is read (at a fourth time) while applying the second voltage (e.g. V2 (114)) to the second word line 152 to generate fourth sense data. Either the third sense data or the fourth sense data is selected based on the corresponding DLA flags stored within the flag latch 160. Thus, the method may select the third sense data or the fourth sense data based on the DLA flags generated during processing of the first read request (i.e., during the first DLA read mode command) in order to determine the second page data for the second read request (i.e., during the second DLA read mode command). The second page data 132 is provided to the host device 130 in response to the second read request 134.

By use of the above method, the operations involved in sensing the data at the second word line 152 are performed a single time for the two read request operations (the first read of the lower page 156 and the second read of the upper page 158). Thus, the method avoids performing multiple reads of the second word line 152. The method also advantageously avoids performing multiple DLA processing operations to convert data read from the second word line 152 to generate flags stored within the flag latch 160. Thus, access time using the above-described method is improved. As a further example, while a conventional DLA read mode operation may require twelve sensing operations per word line, the above-described method performs nine sensing operations per word line. Thus, processing resources are conserved and access time is improved.

In order to provide increased benefits of use of the above-described method, the controller 120 may change an order of a sequence of read requests 134 received from the host 130. For example, the controller 120 may receive a request to read data stored at a plurality of ordered pages according to a first page order. The method includes issuing a plurality of page read commands. The plurality of page read commands identify pages in a second read order. The first order (e.g., sequential) is different from the second page order (e.g., non-sequential). In a particular example, each of the page read commands is a DLA type command, and the flag latch 160 is loaded a number of times that is less than the number of page read commands. The DLA type command corresponds to performing a DLA operation that includes reading a page while applying a first voltage to a second word line to generate first sensed data and reading the page while applying a second voltage to the second word line to generate second sensed data. Performing the DLA operation further includes selecting the first sensed data or the second sensed data based on a DLA flag stored in a latch.

For example, the page reordering may be executed by the controller 120 to reorder memory page requests issued to the memory 104. As an example, the page requests may be reordered from a sequence of “0, 1, 2, 3, 4, 5, 6, 7” to the sequence “0, 2, 1, 4, 3, 6, 5, 7”. The reordered sequence provides an opportunity for reducing a number of word line reads using DLA operations, as described in further detail with respect to Tables 1-2. Thus, additional resources are conserved and access time for performing DLA operations is improved.

While a general method of performing DLA operations has been described, the data storage device 102 may implement various DLA operations and methods. For example, the data storage device 102 may implement DLA operations in a memory only option. In the memory only option, a DLA flag detector may be built inside the memory 104. The DLA flag detector may detect if the flag latch 160 already contains DLA flag data for an incoming read command. If the flag latch 160 already contains the DLA flag data, then the step of reading the subsequent word line (e.g., the second word line 152 in the case of a request to read the lower page 156 of the first word line 150) may be skipped.

In another implementation, functions may be implemented at the memory and at the controller, and the memory and the controller may cooperate to perform the DLA operations. For example, the controller 120 may be configured to inform the memory 104 to skip reading of the second word line 152 (e.g., when the read request 134 is a request to read the upper page 158 of the first word line 150). The memory-controller cooperation implementation may include a command that uses a half DLA mode that skips reading of the subsequent word line (e.g. the second word line 152).

In such an embodiment, the memory die 103 may not include a detector module to determine whether flags can be generated without further sensing; instead, the memory die 103 may be responsive to the controller 120 for the determination. In this case, the controller 120 notifies the memory die 103 prior to each read command (in which next word line reading may be skipped) that the memory should skip sensing and should process data from its internal latches for generating the DLA flags. Subsequently, the memory die 103 transfers the flags to the flag latch 160 and then uses the resulting contents of the flag latch 160 for reading the target word line (e.g., in DLA mode).

An example implementation in which the controller 120 notifies the memory die 103 that the next word line need not be read and that the flags should be computed based on current latch content includes defining in the memory a new prefix to the read commands. The new prefix indicates that the current command is to be performed without reading the next word line (by processing internal latches for generating flags) and is to load the flag latch 160 and use flag data in the flag latch 160 for reading the target word line in DLA mode. Another example implementation includes allocating one bit of the address of a read command to indicate that the current command is to be performed without reading the next word line (by processing internal latches for generating flags) and is to load the flag latch 160 and use the flag data in the flag latch for reading the target word line in DLA mode. The memory-controller cooperation implementation may also include use of other commands, such as any of the illustrated commands 140-146.

Although examples are provided illustrating operation according to a DLA implementation, in other implementations the data storage device 102 of FIG. 1 may instead (or additionally) use LA mode. In such implementations V1 112 and V2 114 may represent a set of one or more reference reading voltages, where the voltages of V1 112 are shifted to a higher voltage value than the corresponding voltage in V2 114.

Referring to FIG. 2, a timeline that illustrates a DLA operation is shown. The timeline illustrates various actions that may be performed by the controller 120 of the data storage device 102 starting at a time 0 and proceeding through time periods 1-5. At an initial time (time 1 in FIG. 2), a read command is received. The read command may correspond to the read request 134 to read a first page of a first word line. For example, the read command may request to read the upper page 158 of the first word line 150. In this example, data has been previously stored in the flag latch 160. For example, DLA flags that were calculated by processing data from the data latches 162 (during a previous read command to read the lower page 156) remain stored within the flag latch 160. Thus, DLA flags have been previously generated and stored within the flag latch 160, and the DLA flags may be used for the read command received at the first time (time 1).

After the read command is received, a first page in the first word line may be sensed while applying a first voltage to the second word line. For example, data within the upper page 158 may be sensed while applying the first voltage V1 112 to the second word line 152 (WL2). After sensing the first page at a second time (e.g., at time 2), the first page may be sensed at a third time (e.g., at time 3). The sensing of the first page at the third time (e.g., at time 3) occurs while a second voltage is applied to the second word line. For example, data within the upper page 158 may be sensed while applying the second voltage V2 114 to the second word line 152. After the first page is sensed at the second time (at time 2) and is subsequently sensed at the third time (at time 3), the first sensed data and the second sensed data are compared (e.g., at time 4). The method includes selecting from the first sensed data and the second sensed data for each cell using the DLA flag corresponding to the cell. The comparison of the first sensed data and the second sensed data using the DLA flags identifies whether to select data from the first sensed data or data from the second sensed data for each cell of the first page. The selection is made based on the DLA flag data retrieved from the flag latch 160. Thus, DLA flags stored within the flag latch 160 prior to receiving the read command (i.e., prior to time 1) are used to perform the DLA comparison operation to select data for the first page. After the comparison of the first sensed data and the second sensed data using the DLA flags, resulting data for the first page is determined and the resulting data is returned (e.g., at time 5). For example, the resulting data from reading the upper page 158 is determined and is provided as the data 132 that is sent to the host device 130.

Table 1 provides an example of a memory, such as the memory 104 of FIG. 1, storing eight logical pages (page 0-page 7) in four word lines (word line 0-word line 3). In the example of Table 1, sequential pages are stored in each word line (e.g., page 0 and page 1 are stored in word line 0).

TABLE 1

| | Lower Pages | Upper Pages |
|---|---|---|
| Word Line 3 | Page 6 | Page 7 |
| Word Line 2 | Page 4 | Page 5 |
| Word Line 1 | Page 2 | Page 3 |
| Word Line 0 | Page 0 | Page 1 |

A series of operations that may be performed by the controller 120 of FIG. 1 and at the memory die 103 to read pages 0-7 may include:
1. Controller sends “read page 0” command (e.g., using the first command 140)
2. Memory senses word line 1 to generate flag data for word line 0
3. Word line 1 data is processed to generate DLA flags, DLA flags are stored in a memory latch serving as the “DLA latch”
4. Memory senses word line 0 lower page twice, selecting for each cell the result of the first sensing of word line 0 or of the second sensing of word line 0 according to the cell's corresponding DLA flag
5. Controller reads out page 0 data from a data latch of the memory
6. Controller sends “read page 1” command (e.g., using the second command 142)
7. Memory senses word line 0 upper page twice, selecting a result for each cell according to its corresponding DLA flag
8. Controller reads out page 1 data from a data latch of the memory
9. Controller sends “read page 2” command (e.g., using the first command 140)
10. Memory senses word line 2 to generate flag data for word line 1
11. Word line 2 data is processed to generate DLA flags, DLA flags are stored in a memory latch serving as the “DLA latch”
12. Memory senses word line 1 lower page twice, selecting a result for each cell according to its corresponding DLA flag
13. Controller reads out page 2 data from a data latch of the memory
14. Controller sends “read page 3” command (e.g., using the second command 142)
15. Memory senses word line 1 upper page twice, selecting a result for each cell according to its corresponding DLA flag
16. Controller reads out page 3 data from a data latch of the memory

Pages 4-6 may be sequentially read from the memory in a manner similar to the method as described with respect to pages 0-3. As described, every word line (except the last one) is read using only 9 sensing operations (compared to 12 in a conventional DLA scheme)—three sensing operations of the next word line (that are used to generate flag data for both pages of the target word line), three sensing operations for the target word line using the first voltage 112, and three sensing operations for the target word line using the second voltage 114.

Table 2 provides an example of a memory, such as the memory 104 of FIG. 1, storing eight logical pages (page 0-page 7) in four word lines (word line 0-word line 3). In the example of Table 2, sequential pages are not stored in the same word line (e.g., page 0 and page 1 are stored in separate word lines). Table 2 may correspond to a memory that implements a lower-middle (LM) scheme to reduce cross-coupling effects.

TABLE 2

| | Lower Pages | Upper Pages |
|---|---|---|
| Word Line 3 | Page 5 | Page 7 |
| Word Line 2 | Page 3 | Page 6 |
| Word Line 1 | Page 1 | Page 4 |
| Word Line 0 | Page 0 | Page 2 |

The controller 120 may arrange the sequence of read page commands into an order that enables sharing of DLA flags between pages sharing a common word line. A series of operations that may be performed by the controller 120 of FIG. 1 and at the memory die 103 to read pages 0-7 may include:
1. Controller sends “read page 0” command (e.g., using the first command 140)
2. Memory senses word line 1 to generate flag data for word line 0
3. Word line 1 data is processed to generate DLA flags, DLA flags are stored in a memory latch serving as the “DLA latch”
4. Memory senses word line 0 lower page twice, selecting for each cell the result of the first sensing of word line 0 or of the second sensing of word line 0 according to the cell's corresponding DLA flag
5. Controller reads out page 0 data from a data latch of the memory
6. Controller sends “read page 2” command (e.g., using the second command 142)
7. Memory senses word line 0 upper page twice, selecting a result for each cell according to its corresponding DLA flag
8. Controller reads out page 2 data from a data latch of the memory
9. Controller sends “read page 1” command (e.g., using the first command 140)
10. Memory senses word line 2 to generate flag data for word line 1
11. Word line 2 data is processed to generate DLA flags, DLA flags are stored in a memory latch serving as the “DLA latch”
12. Memory senses word line 1 lower page twice, selecting a result for each cell according to its corresponding DLA flag
13. Controller reads out page 1 data from a data latch of the memory
14. Controller sends “read page 4” command (e.g., using the second command 142)
15. Memory senses word line 1 upper page twice, selecting a result for each cell according to its corresponding DLA flag
16. Controller reads out page 4 data from a data latch of the memory

Pages 3, 6, 5, and 7 may be sequentially read from the memory in a manner similar to the method as described with respect to pages 0, 2, 1, and 4. As described with respect to Table 1, every word line (except the last one) is read using only 9 sensing operations.

The above example illustrates arranging the sequence of page reads in such a way that one read operation provides flag data for two different pages. However, additional efficiency may be attained by performing a single read for a page that is to be read in response to the controller request for the page and also for generation of flag data. A sequence of page reads may be arranged so that one read operation provides data for a controller-invoked page read and also for a memory-invoked DLA page read.

Returning to the example of Table 1, when a host requests a sequence of page 0, page 1, page 2, . . . , page 7, the controller may reorder the page read sequence to reduce a total number of read operations at the memory:
1. Controller sends “read page 6” command
2. Memory senses word line 3 lower page once (assuming word line 3 is a last word line in an erase block, DLA is not performed)
3. Controller reads out page 6 data from a data latch of the memory (and a copy of page 6 data is kept in a first data latch)
4. Controller sends “read page 7” command
5. Memory senses word line 3 upper page once
6. Controller reads out page 7 data from a data latch of the memory (and a copy of page 7 data is kept in a second data latch)
7. Memory processes word line 3 data (e.g., pages 6-7) in the latches to generate DLA flags for word line 2, DLA flags are stored in a memory latch serving as the “DLA latch” (e.g., in response to the third command 144)
8. Controller sends “read page 4” command (e.g., using the second command 142)
9. Memory senses word line 2 lower page twice, selecting a result for each cell according to its corresponding DLA flag
10. Controller reads out page 4 data from a data latch of the memory (and a copy of page 4 data is kept in the first data latch)
11. Controller sends “read page 5” command (e.g., using the second command 142)
12. Memory senses word line 2 upper page twice, selecting a result for each cell according to its corresponding DLA flag
13. Controller reads out page 5 data from a data latch of the memory (and a copy of page 5 data is kept in the second data latch)
14. Memory processes word line 2 data (e.g., pages 4-5) in the latches to generate DLA flags for word line 1, DLA flags are stored in a memory latch serving as the “DLA latch” (e.g., in response to the third command 144)

Pages 2, 3, 0, 1 may be sequentially read from the memory in a manner similar to the method as described with respect to pages 4-7. As described, every word line (except the last one) is read using only 6 sensing operations.

With the LM-type memory as depicted in Table 2, a similar efficiency may be attained using the same sequence as above except that the order of the pages requested by the controller is different, such as:
1. Controller sends “read page 5” command
2. Memory senses word line 3 lower page once (assuming word line 3 is a last word line in an erase block, DLA is not performed)
3. Controller reads out page 5 data from a data latch of the memory (and a copy of page 5 data is kept in a first data latch)
4. Controller sends “read page 7” command
5. Memory senses word line 3 upper page once
6. Controller reads out page 7 data from a data latch of the memory (and a copy of page 7 data is kept in a second data latch)
7. Memory processes word line 3 data (e.g., pages 5 and 7) in the latches to generate DLA flags for word line 2, DLA flags are stored in a memory latch serving as the “DLA latch” (e.g., in response to the third command 144)
8. Controller sends “read page 3” command (e.g., using the second command 142)
9. Memory senses word line 2 lower page twice, selecting a result for each cell according to its corresponding DLA flag
10. Controller reads out page 3 data from a data latch of the memory (and a copy of page 3 data is kept in the first data latch)
11. Controller sends “read page 6” command (e.g., using the second command 142)
12. Memory senses word line 2 upper page twice, selecting a result for each cell according to its corresponding DLA flag
13. Controller reads out page 6 data from a data latch of the memory (and a copy of page 6 data is kept in the second data latch)
14. Memory processes word line 2 data (e.g., pages 3 and 6) in the latches to generate DLA flags for word line 1, DLA flags are stored in a memory latch serving as the “DLA latch” (e.g., in response to the third command 144)

Pages 1, 4, 0, and 2 may be sequentially read from the memory in a manner similar to the method as described with respect to pages 5, 7, 3, and 6. As described, every word line (except the last one) is read using only 6 sensing operations.

Referring to FIG. 3, a method 300 for reading data from a flash memory device is illustrated. For example, the method 300 may be performed by the control circuitry 164 and the flash memory device may correspond to memory die 103 of FIG. 1.

At 302, a first logical page stored in a first word line is read. Reading the first logical page includes sensing a second word line and storing flags in a latch within the flash memory device. The flags are set according to the sensing of the second word line and each flag corresponds to a cell of the first word line. For example, the first logical page may be the lower page 156 stored in the first word line 150 and the second word line may be the second word line 152 of FIG. 1. The flags may be stored in the flag latch 160 based on sensing the second word line 152.

At 304, subsequent to reading the first logical page, a command to read a second logical page is received. The second logical page is different from the first logical page and the second logical page is stored in the first word line. For example, after reading the lower page 156 in the first word line 150, the command may be received from the controller 120 to read the upper page 158 in the first word line 150.

At 306, in response to receiving the command, the second logical page is read. The second word line is not sensed in response to receiving the command.

Reading the second logical page includes sensing the second logical page at a first time while applying a first voltage to one of the first word line and the second word line to generate first sensed data for each cell of the first word line that stores a bit of the second logical page, at 308. Reading the second logical page includes sensing the second logical page at a second time while applying a second voltage to the one of the first word line and the second word line to generate second sensed data for each of the cells of the first word line that stores a bit of the second logical page, at 310. The second voltage is different from the first voltage.

For example, in a differential look ahead (DLA) mode, the first voltage V1 112 may be applied to the second word line 152 when reading the first word line 150 at the first time. The second voltage V2 114 may be applied to the second word line 152 when reading the first word line 150 at the second time. As another example, in a look ahead (LA) mode, the first voltage V1 112 may be applied to the first word line 150 when reading the first word line 150 at the first time, and the second voltage V2 114 may be applied to the first word line 150 when reading the first word line 150 at the second time.

Reading the second logical page includes, for each of the cells of the first word line that stores a bit of the second logical page, selecting the first sensed data or the second sensed data based on the corresponding flag in the latch, at 312. For example, the first sensed data may be selected for a cell in response to a flag (in the flag latch 160) for the cell having a first value, and the second sensed data may be selected for the cell in response to the flag having a second value.

The command may be received subsequent to a prior read command. For example, a prior read command may be received to read the lower page 156, followed by the command to read the upper page 158. To illustrate, the first command 140 may be received by the control circuitry 164 to populate the flag latch based on sensing the second word line 152 prior to reading the lower page 156 of the first word line 150, so that the flag data in the flag latch 160 corresponds to the second word line 152.

The command may be received subsequent to a prior latch population command. For example, the command may follow the third command 144 or the fourth command 146 to populate the flag latch 160 with flag data corresponding to the second word line 152.

Referring to FIG. 4, a method 400 for reading data from a flash memory device is illustrated. For example, the method 400 may be performed by the control circuitry 164 and the flash memory device may correspond to memory die 103 of FIG. 1.

At 402, a first word line is read. Reading the first word line includes storing first data associated with the first word line in one or more latches within the flash memory device. For example the first word line may be WL1 152 of FIG. 1 and the data read from WL1 152 may be stored in the data latches 162.

At 404, subsequent to reading the first word line, a first command to prepare for reading second data from a second word line is received. The second word line is different from the first word line. For example the command may be the third command 144 of FIG. 1 to populate the flag latch 160 using the data read from WL1 152 that is stored in the data latches 162.

The method 400 includes, in response to receiving the first command, preparing for reading the second data from the second word line, at 406. Preparing for reading the second data includes storing flags in a latch within the flash memory device. The flags are set according to the first data in the one or more latches and each flag corresponds to a cell of the second word line, such as described with respect to the third command 144 of FIG. 1. The first word line (e.g., WL1 152) is not sensed in response to receiving the first command.

At 408, subsequent to receiving the first command, a second command is received to read the second data from the second word line. For example, the second command may correspond to the second command 142 of FIG. 1 to read the lower page 156 of WL0 150. The first word line (e.g., WL1 152) is not sensed in response to receiving the second command.

At 410, in response to receiving the second command, the second data is read from the second word line. Each cell in the second word line that stores the second data is read according to the corresponding flag in the latch. For example, in a differential look ahead (DLA) mode, the first voltage V1 112 may be applied to the second word line 152 when reading the first word line 150 at a first time and a first result may be stored in the data latches 162. The second voltage V2 114 may be applied to the second word line 152 when reading the first word line 150 at a second time and a second result may be stored in the data latches 162. As another example, in a look ahead (LA) mode, the first voltage V1 112 may be applied to the first word line 150 when reading the first word line 150 at a first time and a first result may be stored in the data latches 162. The second voltage V2 114 may be applied to the first word line 150 when reading the first word line 150 at a second time and a second result may be stored in the data latches 162. Data may be read for a cell according to the corresponding flag in the flag latch 160 by selecting the first result for the cell in response to a flag (in the flag latch 160) for the cell having a first value, and selecting the second result for the cell in response to the flag having a second value.

Referring to FIG. 5, a method 500 for reading data from a flash memory device is illustrated. For example, the method 500 may be performed by the control circuitry 164 and the flash memory device may correspond to memory die 103 of FIG. 1.

At 502, a first word line is read. Reading the first word line includes storing first data associated with the first word line in one or more latches within the flash memory device. For example, the first word line may be WL1 152 of FIG. 1 and the first data may be stored in the data latches 162.

At 504, subsequent to reading the first word line, a command to read second data from a second word line is received. The second word line is different from the first word line. The command may correspond to the fourth command 146 of FIG. 1 to populate the flag latch 160 with flag data and to read data from WL0 according to the flag data.

At 506, in response to receiving the command, the second data is read from the second word line (e.g., WL0 150). The first word line (e.g., WL1 152) is not sensed in response to receiving the command. Reading the second data includes, at 508, storing flags in a latch within the flash memory device. The flags are set according to the first data in the one or more latches and each flag corresponds to a cell of the second word line. For example, the flags may be set in the flag latch 160 based on one or more logical operations applied to the data (read from WL1 152) that is in the data latches 162).

Reading the second data includes, at 510, reading the second data from the second word line. Each cell in the second word line that stores the second data is read according to the corresponding flag in the latch. For example, in a differential look ahead (DLA) mode, the first voltage V1 112 may be applied to WL1 152 when reading WL0 150 at a first time and a first result may be stored in the data latches 162. The second voltage V2 114 may be applied to WL1 152 when reading WL0 150 at a second time and a second result may be stored in the data latches 162. As another example, in a look ahead (LA) mode, the first voltage V1 112 may be applied to WL0 150 when reading WL0 150 at a first time and a first result may be stored in the data latches 162. The second voltage V2 114 may be applied to WL0 150 when reading WL0 150 at a second time and a second result may be stored in the data latches 162. Data may be read for a cell according to the corresponding flag in the flag latch 160 by selecting the first result for the cell in response to a flag (in the flag latch 160) for the cell having a first value, and selecting the second result for the cell in response to the flag having a second value.

Referring to FIG. 6, a method 600 for reading a group of pages is illustrated. For example, the method 600 may be performed in a data storage device that includes a controller and a flash memory device, such as the data storage device 102 of FIG. 1 that includes the controller 120 and the memory die 103 of FIG. 1.

At 602, a request is received to read the group of pages. The request is received at the controller. At 604, a plurality of page read commands are issued from the controller to the flash memory device. Each of the pages in the group corresponds to one of the plurality of page read commands.

At 606, in response to receiving each of the plurality of page read commands, the page corresponding to the page read command is read at the flash memory device according to flags stored in a latch within the flash memory device. Each of the flags corresponds to a cell in a word line that stores the page. A total number of times the latch is loaded in response to receiving the plurality of page read commands is less than a number of the plurality of page read commands.

For example, the pages in the group may be stored in the flash memory device according to a first page order, and the plurality of page read commands may identify the pages in a second page order. The first page order may be sequential and the second page order may be non-sequential. To illustrate, the pages illustrated in Table 1 are in sequential order (page 0-page 7), and may be read in a non-sequential order (e.g., page 6, 7, 4, 5, 2, 3, 0, 1) to reduce a number of sensing operations by generating flag data for one word line based on data in the data latches 162 from another word line. The first page order and the second page order may both be non-sequential. For example, the pages illustrate in Table 2 are stored in the memory in a page order 0, 2, 1, 4, 3, 6, 5, 7 and may be read in the order 5, 7, 3, 6, 1, 4, 0, 2. In both examples, the flag latch 160 may be loaded one time for every word line (e.g., one set of flags loaded for every two pages).

Referring to FIG. 7, a method 700 for reading data from a flash memory device is illustrated. For example, the method 700 may be performed by the control circuitry 164 and the flash memory device may correspond to memory die 103 of FIG. 1.

At 702, a first word line is sensed. Sensing the first word line includes storing flags in a latch within the flash memory device. The flags are set according to the sensing and each of the flags corresponds to a cell of the first word line. To illustrate, WL1 152 may be sensed and flags may be generated based on sense data of WL1 152 and stored in the flag latch 160.

At 704, information related to an identity of the first word line is stored within the flash memory device. For example, the control circuitry 164 may set an indicator (e.g., a word line address, a word line index, or other identifier) that is stored in the memory die 104, such as at a latch or register accessible to the control circuitry 164. The indicator may be used to track a source of the flag data in the flag latch 160.

At 706, subsequent to sensing the first word line, a command to read data from a second word line is received. The second word line is different from the first word line. For example, the command may be a command to read the lower page 156 of WL0 150.

At 708, in response to receiving the command, the data is read from the second word line. Reading the data from the second word line includes, at 710, evaluating, by the flash memory device, a condition corresponding to whether the first word line is the next word line to the second word line and in a same block as the second word line. To illustrate, the control circuitry 164 may compare the indicator (e.g., an address or index of the word line that is the source of the flag data in the flag latch 160) to an address or index of the word line to be read. The condition may be evaluated to be true if the indicator (e.g., to WL1) corresponds to the next word line to the word line to be read (e.g., WL0) and in the same block (e.g., WL1 152 and WL0 150 are in the same block).

If the condition is evaluated to be true, at 712, the data is read from the second word line. Each cell of the second word line that stores the data is read according to one flag of the flags in the latch, where the one flag corresponds to a cell of the first word line that shares a bit line with the cell of the second word line. For example, in a differential look ahead (DLA) mode, the first voltage V1 112 may be applied to WL1 152 when reading WL0 150 at a first time and a first result may be stored in the data latches 162. The second voltage V2 114 may be applied to WL1 152 when reading WL0 150 at a second time and a second result may be stored in the data latches 162. As another example, in a look ahead (LA) mode, the first voltage V1 112 may be applied to WL0 150 when reading WL0 150 at a first time and a first result may be stored in the data latches 162. The second voltage V2 114 may be applied to WL0 150 when reading WL0 150 at a second time and a second result may be stored in the data latches 162. Data may be read for a cell according to the corresponding flag in the flag latch 160 by selecting the first result for the cell in response to a flag (in the flag latch 160) for the cell having a first value, and selecting the second result for the cell in response to the flag having a second value.

The first word line is not sensed in response to receiving the command. The flash memory device may selectively apply an enhanced read operation (e.g., DLA or LA) when the flag data is available and may perform a standard read operation when flag data is not available or when available flag data does not correspond to the next word line (in the same erase block) of the target word line.

Referring to FIG. 8, a method 800 for reading data from a flash memory device is illustrated. For example, the method 800 may be performed by the control circuitry 164 and the flash memory device may correspond to memory die 103 of FIG. 1.

At 802, a first word line is sensed. Sensing the first word line includes storing first data associated with the first word line in one or more latches within the flash memory device. To illustrate, WL1 152 may be sensed and the sense data may be stored in the data latches 162.

At 804, information related to an identity of the first word line is stored within the flash memory device. For example, the control circuitry 164 may set an indicator (e.g., a word line address, a word line index, or other identifier) that is stored in the memory die 104, such as at a latch or register accessible to the control circuitry 164. The indicator may be used to track a source of the sense data in the data latches 162.

At 806, subsequent to sensing the first word line, a command is received to read second data from a second word line. The second word line is different from the first word line (e.g., WL0 150). At 808, in response to receiving the command, the second data is read from the second word line. Reading the second data includes evaluating, by the flash memory device, a condition corresponding to whether the first word line is the next word line to the second word line and in a same block as the second word line, at 810. To illustrate, the control circuitry 164 may compare the indicator (e.g., an address or index of the word line that is the source of the sense data in the data latches 162) to an address or index of the word line to be read. The condition may be evaluated to be true if the indicator (e.g., to WL1) corresponds to the next word line to the word line to be read (e.g., WL0) and in the same block (e.g., WL1 152 and WL0 150 are in the same block).

Flags may be stored in a particular latch within the flash memory device, at 812. The flags are set according to the first data in the one or more latches and each of the flags corresponds to a cell of the second word line. For example, one or more logical operations may be performed on the sense data of WL1 152 in the data latches 162 to generate flag data that is stored into the flag latch 160.

At 814, if the condition is evaluated to be true, the second data is read from the second word line. Each cell in the second word line that stores the data is read according to the corresponding flag in the particular latch. For example, in a differential look ahead (DLA) mode, the first voltage V1 112 may be applied to WL1 152 when reading WL0 150 at a first time and a first result may be stored in the data latches 162. The second voltage V2 114 may be applied to WL1 152 when reading WL0 150 at a second time and a second result may be stored in the data latches 162. As another example, in a look ahead (LA) mode, the first voltage V1 112 may be applied to WL0 150 when reading WL0 150 at a first time and a first result may be stored in the data latches 162. The second voltage V2 114 may be applied to WL0 150 when reading WL0 150 at a second time and a second result may be stored in the data latches 162. Data may be read for a cell according to the corresponding flag in the flag latch 160 by selecting the first result for the cell in response to a flag (in the flag latch 160) for the cell having a first value, and selecting the second result for the cell in response to the flag having a second value.

The first word line is not sensed in response to receiving the command. The flash memory device may selectively apply an enhanced read operation (e.g., DLA or LA) when the sense data is available to generate flag data and may perform a standard read operation when sense data is not available or when available sense data does not correspond to the next word line (in the same block) of the target word line.

Although various components depicted herein are illustrated as block components and described in general terms, such components may include one or more microprocessors, state machines, or other circuits configured to enable the data storage device 102 of FIG. 1 to perform DLA operations. For example, the controller 120 may represent physical components, such as hardware controllers, state machines, logic circuits, or other structures, to enable the data storage device 102 of FIG. 1 to perform DLA operations.

The controller 120 may be implemented using a microprocessor or microcontroller programmed to perform DLA operations as described herein. In a particular embodiment, the controller 120 includes a processor executing instructions that are stored at the non-volatile memory 104. Alternatively, or in addition, executable instructions that are executed by the processor may be stored at a separate memory location that is not part of the non-volatile memory 104, such as at a read-only memory (ROM).

In a particular embodiment, the data storage device 102 may be implemented in a portable device configured to be selectively coupled to one or more external devices. However, in other embodiments, the data storage device 102 may be attached or embedded within one or more host devices, such as within a housing of a host communication device. For example, the data storage device 102 may be within a packaged apparatus such as a wireless telephone, a personal digital assistant (PDA), a gaming device or console, a portable navigation device, or other device that uses internal non-volatile memory. In a particular embodiment, the data storage device 102 may be coupled to a non-volatile memory, such as a three-dimensional (3D) memory, a flash memory (e.g., NAND, NOR, Multi-Level Cell (MLC), a Divided bit-line NOR (DINOR) memory, an AND memory, a high capacitive coupling ratio (HiCR), asymmetrical contactless transistor (ACT), or other flash memories), an erasable programmable read-only memory (EPROM), an electrically-erasable programmable read-only memory (EEPROM), a read-only memory (ROM), a one-time programmable memory (OTP), or any other type of memory.

The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for reading data from a flash memory device, comprising:
reading a first logical page stored in a first word line, wherein reading the first logical page includes sensing a second word line and storing flags in a latch within the flash memory device, wherein the flags are set according to the sensing of the second word line and wherein each flag corresponds to a cell of the first word line;
subsequent to reading the first logical page, receiving a command to read a second logical page, wherein the second logical page is different from the first logical page and wherein the second logical page is stored in the first word line;
in response to receiving the command, reading the second logical page, wherein reading the second logical page includes:
sensing the second logical page at a first time while applying a first voltage to one of the first word line and the second word line to generate first sensed data for each cell of the first word line that stores a bit of the second logical page;
sensing the second logical page at a second time while applying a second voltage to the one of the first word line and the second word line to generate second sensed data for each of the cells of the first word line that stores a bit of the second logical page, wherein the second voltage is different from the first voltage; and
for each of the cells of the first word line that stores a bit of the second logical page, selecting the first sensed data or the second sensed data based on the corresponding flag in the latch,
wherein the second word line is not sensed in response to receiving the command.

2. The method of claim 1, wherein reading the first logical page is performed in response to a read command.

3. The method of claim 1, wherein reading the first logical page is performed in response to a command to populate the latch.

4. The method of claim 1, wherein the second word line is a neighbor of the first word line.

5. A method for reading data from a flash memory device, the method comprising:
reading a first word line, wherein reading the first word line includes storing first data associated with the first word line in one or more latches within the flash memory device;
subsequent to reading the first word line, receiving a first command to prepare for reading second data from a second word line, wherein the second word line is different from the first word line;
in response to receiving the first command, preparing for reading the second data from the second word line, wherein preparing for reading the second data includes storing flags in a latch within the flash memory device, wherein the flags are set according to the first data in the one or more latches and wherein each flag corresponds to a cell of the second word line;
subsequent to receiving the first command, receiving a second command to read the second data from the second word line; and
in response to receiving the second command, reading the second data from the second word line, wherein each cell in the second word line that stores the second data is read according to the corresponding flag in the latch;
wherein the first word line is not sensed in response to receiving the first command and wherein the first word line is not sensed in response to receiving the second command.

6. A method for reading data from a flash memory device, the method comprising:
reading a first word line, wherein reading the first word line includes storing first data associated with the first word line in one or more latches within the flash memory device;
subsequent to reading the first word line, receiving a command to read second data from a second word line, wherein the second word line is different from the first word line; and
in response to receiving the command, reading the second data from the second word line, wherein reading the second data includes:
storing flags in a latch within the flash memory device, wherein the flags are set according to the first data in the one or more latches and wherein each flag corresponds to a cell of the second word line; and
reading the second data from the second word line, where each cell in the second word line that stores the second data is read according to the corresponding flag in the latch;
wherein the first word line is not sensed in response to receiving the command.

7. The method of claim 6, wherein reading each cell in the second word line that stores the second data includes:
sensing the cells in the second word line that store the second data while applying a first voltage to one of the first word line and the second word line to generate first sensed data;
sensing the cells in the second word line that store the second data while applying a second voltage to the one of the first word line and the second word line to generate second sensed data; and
selecting, for each of the cells in the second word line that stores the second data, the first sensed data or the second sensed data based on the flag that corresponds to the cell.

8. The method of claim 7, wherein the second word line is a neighbor of the first word line.

9. In a data storage device including a controller and a flash memory device, a method for reading a group of pages, the method comprising:
receiving a request to read the group of pages, wherein the request is received at the controller;
issuing, from the controller to the flash memory device, a plurality of page read commands, wherein each of the pages in the group corresponds to one of the plurality of page read commands; and
in response to receiving each of the plurality of page read commands, reading the page corresponding to the page read command at the flash memory device according to flags stored in a latch within the flash memory device, wherein each of the flags corresponds to a cell in a word line that stores the page, and wherein a total number of times the latch is loaded in response to receiving the plurality of page read commands is less than a number of the plurality of page read commands.

10. The method of claim 9, wherein the pages in the group are stored in the flash memory device according to a first page order, wherein the plurality of page read commands identify the pages in a second page order, and wherein the first page order is sequential and the second page order is non-sequential.

11. A method for reading data from a flash memory device, the method comprising:
sensing a first word line, wherein sensing the first word line includes storing flags in a latch within the flash memory device, wherein the flags are set according to the sensing and each of the flags corresponds to a cell of the first word line;
storing, within the flash memory device, information related to an identity of the first word line;
subsequent to sensing the first word line, receiving a command to read data from a second word line, wherein the second word line is different from the first word line; and
in response to receiving the command, reading the data from the second word line, wherein reading the data includes:
evaluating, by the flash memory device, a condition corresponding to whether the first word line is the next word line to the second word line and in a same block as the second word line; and
if the condition is evaluated to be true, reading the data from the second word line, wherein each cell of the second word line that stores the data is read according to one flag of the flags in the latch, wherein the one flag corresponds to a cell of the first word line that shares a bit line with the cell of the second word line;
wherein the first word line is not sensed in response to receiving the command.

12. A method for reading data from a flash memory device, the method comprising:
sensing a first word line, wherein sensing the first word line includes storing first data associated with the first word line in one or more latches within the flash memory device;
storing, within the flash memory device, information related to an identity of the first word line;
subsequent to sensing the first word line, receiving a command to read second data from a second word line, wherein the second word line is different from the first word line; and
in response to receiving the command, reading the second data from the second word line, wherein reading the second data includes:
evaluating, by the flash memory device, a condition corresponding to whether the first word line is the next word line to the second word line and in a same block as the second word line;
storing flags in a particular latch within the flash memory device, wherein the flags are set according to the first data in the one or more latches and wherein each of the flags corresponds to a cell of the second word line; and
if the condition is evaluated to be true, reading the second data from the second word line, wherein each cell in the second word line that stores the data is read according to the corresponding flag in the particular latch;
wherein the first word line is not sensed in response to receiving the command.

13. A flash memory device, comprising:
a plurality of word lines; and
control circuitry configured to:
read a first logical page stored in a first word line, wherein reading the first logical page includes sensing a second word line and storing flags in a latch, wherein the flags are set according to the sensing of the second word line and wherein each of the flags corresponds to a cell of the first word line;
subsequent to reading the first logical page, receive a command to read a second logical page, wherein the second logical page is different from the first logical page, and wherein the second logical page is stored in the first word line; and
in response to receiving the command, read the second logical page, wherein reading the second logical page includes:
sensing the second logical page at a first time while applying a first voltage to one of the first word line and the second word line to generate first sensed data for each cell of the first word line that stores a bit of the second logical page;
sensing the second logical page at a second time while applying a second voltage to the one of the first word line and the second word line to generate second sensed data for each of the cells of the first word line that stores a bit of the second logical page, wherein the second voltage is different from the first voltage; and
for each of the cells of the first word line that stores a bit of the second logical page, selecting the first sensed data or the second sensed data based on the corresponding flag in the latch,
wherein the second word line is not sensed in response to receiving the command.

14. The flash memory device of claim 13, wherein reading the first logical page is performed in response to a read command.

15. The flash memory device of claim 13, wherein reading the first logical page is performed in response to a command to populate the latch.

16. The flash memory device of claim 13, wherein the second word line is a neighbor of the first word line.

17. A flash memory device comprising:
a plurality of word lines; and
control circuitry configured to:
read a first word line, wherein reading the first word line includes storing first data associated with the first word line in one or more latches;
subsequent to reading the first word line, receive a first command to prepare for reading second data from a second word line, wherein the second word line is different from the first word line;
in response to receiving the first command, prepare for reading the second data from the second word line, wherein preparing for reading the second data includes storing flags in a latch within the flash memory device, wherein the flags are set according to the first data in the one or more latches and wherein each of the flags corresponds to a cell of the second word line;
subsequent to receiving the first command, receive a second command to read the second data from the second word line; and
in response to receiving the second command, read the second data from the second word line, wherein each cell in the second word line that stores the second data is read according to the corresponding flag in the latch;
wherein the first word line is not sensed in response to receiving the first command and wherein the first word line is not sensed in response to receiving the second command.

18. A flash memory device comprising:
a plurality of word lines; and
control circuitry configured to:
read a first word line, wherein reading the first word line includes storing first data associated with the first word line in one or more latches;
subsequent to reading the first word line, receive a command to read second data from a second word line, wherein the second word line is different from the first word line; and
in response to receiving the command, read the second data from the second word line, wherein reading the second data includes:
storing flags in a latch, wherein the flags are set according to the first data in the one or more of the latches and wherein each flag corresponds to a cell of the second word line; and
reading the second data from the second word line, where each cell in the second word line that stores the second data is read according to the corresponding flag in the latch;
wherein the first word line is not sensed in response to receiving the command.

19. The flash memory device of claim 18, wherein reading each cell in the second word line that stores the second data includes:
sensing the cells in the second word line that store the second data while applying a first voltage to the first word line to generate first sensed data;
sensing the cells in the second word line that store the second data while applying a second voltage to the first word line to generate second sensed data; and
selecting, for each of the cells in the second word line that store the second data, the first sensed data or the second sensed data based on the flag that corresponds to the cell.

20. The flash memory device of claim 18, wherein the second word line is a neighbor of the first word line.

21. A data storage device comprising:
a flash memory device; and
a controller, wherein the controller is configured to receive a request to read a group of pages at the flash memory device and to issue, from the controller to the flash memory device, a plurality of page read commands, wherein each of the pages in the group corresponds to one of the plurality of page read commands, and
wherein the flash memory device is configured, in response to receiving each of the plurality of page read commands, to read the page corresponding to the page read command according to flags stored in a latch within the flash memory device, wherein each of the flags corresponds to a cell in a word line that stores the page, and wherein a total number of times the latch is loaded in response to receiving the plurality of page read commands is less than a number of the plurality of page read commands.

22. The data storage device of claim 21, wherein the pages in the group are stored in the flash memory device according to a first page order, wherein the plurality of page read commands identify the pages in a second page order, and wherein the first page order is sequential and the second page order is non-sequential.

23. A flash memory device comprising:
a plurality of word lines; and
control circuitry configured to:
sense a first word line, wherein sensing the first word line includes storing flags in a latch, wherein the flags are set according to the sensing and each of the flags corresponds to a cell of the first word line;
store information related to an identity of the first word line;
subsequent to sensing the first word line, receive a command to read data from a second word line, wherein the second word line is different from the first word line; and
in response to receiving the command, read the data from the second word line, wherein reading the data includes:
evaluating a condition corresponding to whether the first word line is the next word line to the second word line and in a same block as the second word line; and
if the condition is evaluated to be true, reading the data from the second word line, wherein each cell of the second word line that stores the data is read according to one flag of the flags in the latch, wherein the one flag corresponds to a cell of the first word line that shares a bit line with the cell of the second word line;
wherein the first word line is not sensed in response to receiving the command.

24. A flash memory device comprising:
a plurality of word lines; and
control circuitry configured to:
sense a first word line, wherein sensing the first word line includes storing first data associated with the first word line in one or more latches;
store, within the flash memory device, information related to an identity of the first word line;
subsequent to sensing the first word line, receive a command to read second data from a second word line, wherein the second word line is different from the first word line; and
in response to receiving the command, read the second data from the second word line, wherein reading the second data includes:
evaluating a condition corresponding to whether the first word line is the next word line to the second word line and in a same block as the second word line;
storing flags in a particular latch, wherein the flags are set according to the first data in the one or more latches and wherein each of the flags corresponds to a cell of the second word line; and
if the condition is evaluated to be true, reading the second data from the second word line, wherein each cell in the second word line that stores the data is read according to the corresponding flag in the particular latch;
wherein the first word line is not sensed in response to receiving the command.
